(19) United States
(12) Patent Application Publication
(10) Pub. No.: US 2025/0063701 A1
(43) Pub. Date: Feb. 20, 2025

(54) LIQUID COOLING SYSTEM FOR DATA CENTER, CONTROL METHOD, AND EDGE DATA CENTER

(71) Applicant: Hebei Qinhuai Data Co., Limited., Zhangjiakou City (CN)

(72) Inventors: Binghua ZHANG, Zhangjiakou City (CN); Yongbin LIU, Zhangjiakou City (CN)

(21) Appl. No.: 18/805,069

(22) Filed: Aug. 14, 2024

(30) Foreign Application Priority Data
Aug. 15, 2023 (CN) 202311023736.6

(51) Int. Cl. H05K 7/20

(52) U.S. Cl. CPC H05K 7/20809; H05K 7/20309; H05K 7/20318; H05K 7/20436; H05K 7/20745; H05K 7/20836

(57) ABSTRACT

Embodiments of the present disclosure provide a liquid cooling system for a data center, a control method, and an edge data center, relating to the field of data center technology. The liquid cooling system includes: an outdoor condenser, an indoor evaporator, a temperature sensor, and a heating sleeve. The outdoor condenser and the indoor evaporator are connected through a pipeline to form a loop, and the outdoor condenser is arranged higher than the indoor evaporator. The temperature sensor and the heating sleeve are arranged on an outlet pipeline of the outdoor condenser.

### CROSS REFERENCE TO RELATED APPLICATION

This application claims priority to Chinese Patent Application No. 202311023736.6, titled “LIQUID COOLING SYSTEM FOR DATA CENTER, CONTROL METHOD, AND EDGE DATA CENTER” and filed to the China National Intellectual Property Administration on Aug. 15, 2023, the entire contents of which are incorporated herein by reference.

### TECHNICAL FIELD

The present disclosure relates to the field of data center technology, and more particularly, to a liquid cooling system for a data center, a control method, and an edge data center.

### BACKGROUND

Large-scale data centers typically use liquid cooling technologies to meet heat dissipation requirements for servers. At present, relatively low-cost and reliable liquid-cooled data centers typically use a cold plate liquid cooling system. The cold plate liquid cooling system is primarily comprised of a cooling tower, a coolant distribution unit (CDU), and a liquid-cooled cabinet.

In the above-mentioned cold plate liquid cooling system, transportation of primary side cooling water and secondary side liquid cooling coolant depends on a circulating water pump. Moreover, in conventional solutions, a two-stage heat exchange system is arranged, where heat from a server is transferred to the liquid cooling coolant by means of a cold plate. Next, the liquid cooling coolant exchanges heat with the cooling water by means of a heat exchange unit (also known as a heat interchange unit) of the CDU. Finally, the heat from the cooling water is dissipated outdoors by means of the cooling tower. In one aspect, the heat exchange process is relatively complicated, and in another aspect the heat exchange process is not suitable for extreme operating conditions in winter.

### SUMMARY

To solve the technical problem in existing technologies where the heat exchange process is relatively complicated and/or not suitable for extreme operating conditions in winter, embodiments of the present disclosure provide a liquid cooling system for a data center, a control method, and an edge data center. The technical solutions are as follows.

In a first aspect, the present disclosure provides a liquid cooling system for a data center, including an outdoor condenser, an indoor evaporator, a temperature sensor, and a heating sleeve.

The outdoor condenser and the indoor evaporator are connected through a pipeline to form a loop, and the outdoor condenser is arranged higher than the indoor evaporator.

The temperature sensor and the heating sleeve are arranged on an outlet pipeline of the outdoor condenser.

Further, a pressure sensor and a frequency converter are further arranged on the outlet pipeline of the outdoor condenser.

Further, a pressure sensor and a temperature sensor are arranged on an inlet pipeline of the outdoor condenser.

Further, a valve is arranged on the outlet pipeline and the inlet pipeline of the indoor evaporator, respectively.

Further, the indoor evaporator includes an evaporative liquid cooling cold plate, which is attached to a heating element of a server in the data center.

Further, a thermal conductive coating is provided between the heating element and the evaporative liquid cooling cold plate.

In a second aspect, the present disclosure provides an edge data center including a server cabinet and a liquid cooling system, where the edge data center also includes a container shell. The liquid cooling system includes: an outdoor condenser, an indoor evaporator, a temperature sensor, and a heating sleeve.

The outdoor condenser and the indoor evaporator are connected through a pipeline to form a loop, and the outdoor condenser is arranged higher than the indoor evaporator.

The temperature sensor and the heating sleeve are arranged on an outlet pipeline of the outdoor condenser.

Further, the edge data center also includes an indoor inter-row air conditioner and a power distribution monitoring unit, where the power distribution monitoring unit is configured to monitor and control an operating state of the inter-row air conditioner.

Further, the inter-row air conditioner is a fluorine pump air-cooled inter-row air conditioner.

In a third aspect, the present disclosure provides a control method for a liquid cooling system, where the control method is applied to the liquid cooling system according to any one of the embodiments in the first aspect. The control method includes:
detecting a current outlet temperature of the outdoor condenser by means of a temperature sensor;
comparing the current outlet temperature with a preset operating condition; and
determining whether to heat a refrigerant by means of a heating sleeve according to a temperature comparison result.

Further, the control method also includes:
detecting a current outlet pressure of the outdoor condenser by means of a pressure sensor;
comparing the current outlet pressure with the preset operating condition; and
determining whether to regulate a liquid supply pressure of the condenser by means of a frequency converter according to a pressure comparison result.

Further, the preset operating condition includes a preset temperature and a preset pressure.

In one aspect, the liquid cooling system of the present disclosure is simple and compact in structure, good in heat transfer performance, and high in reliability. Circulation of the refrigerant is completed by means of a gravity assisted heat pipe technology, such that the refrigerant in the liquid cooling system does not need to be transported by a conventional water pump, which reduces pumping power consumption. Compared to a conventional two-stage heat exchange system, the present disclosure reduces primary heat exchange, which further improves the energy utilization ratio of a cooling system of the data center, and reduces structural complexity of the system. In another aspect, in the present disclosure, the current outlet temperature of the outdoor condenser is measured by means of the temperature sensor arranged on the outlet pipeline of the condenser, and the operating state of the heating sleeve on the pipeline is controlled according to the temperature data. When extreme operating conditions are encountered in winter and the outdoor temperature is lower, the outlet refrigerant has a larger degree of supercooling, resulting in less refrigerant flowing to the evaporator and drop of pressure. In this case, the heating sleeve may be started to electrically heat the refrigerant, thereby increasing the temperature of the refrigerant in the outlet pipeline of the condenser. In this way, a liquid supply temperature and a liquid supply pressure may be controlled to maintain at the preset operating condition, thereby ensuring that the end liquid supply temperature is higher than an indoor dew point temperature.

### BRIEF DESCRIPTION OF THE DRAWINGS

To describe the technical solutions in the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a liquid cooling system for a data center according to an embodiment of the present disclosure;

FIG. 2 is a schematic structural diagram of a condenser according to an embodiment of the present disclosure;

FIG. 3 is a pressure-enthalpy diagram of a gravity assisted heat pipe system according to an embodiment of the present disclosure; and

FIG. 4 is a schematic structural diagram of an edge data center according to an embodiment of the present disclosure.

### DETAILED DESCRIPTION

To make the objectives, technical solutions and advantages of the present disclosure clearer, the embodiments of the present disclosure are further described as below in details with reference to the accompanying drawings. The terms such as “upper”, “above”, “lower”, “below”, “first end”, “second end”, “one end”, “other end” as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, terms “installed”, “arranged”, “provided”, “connection”, “sliding connection”, “fixed”, and “sleeved” should be understood in a broad sense. For example, the “connection” may be a fixed connection, a detachable connection or integrated connection, a mechanical connection or an electrical connection, a direct connection or indirect connection by means of an intermediary, or internal connection between two apparatuses, elements, or components. The specific significations of the above terms in the present disclosure may be understood in the light of specific conditions by persons of ordinary skill in the art.

Embodiments of the present disclosure provide a liquid cooling system for a data center. As shown in FIG. 1, the liquid cooling system includes: an outdoor condenser, an indoor evaporator, a temperature sensor, and a heating sleeve. The outdoor condenser and the indoor evaporator are connected through a pipeline to form a loop, and the outdoor condenser is arranged higher than the indoor evaporator. The temperature sensor and the heating sleeve are arranged on an outlet pipeline of the outdoor condenser.

In FIG. 1, a line shown by a solid line may represent a water supply pipeline for a refrigerant; a line shown by a dotted line may represent a return water pipeline for the refrigerant; and a double dot dash line may represent a signal transduction circuit.

In implementation, the condenser may be an air-cooled condenser or an evaporative condenser. A position of the outdoor condenser in the present disclosure is higher than that of the indoor evaporator. That is, there is a certain height difference between the outdoor condenser and the indoor evaporator, such that the refrigerant is enough to achieve circulation flow by taking advantage of gravity. Principles of the circulation are as below. By taking advantage of gravity, a refrigerant liquid flows through liquid pipelines such as an outlet pipeline of the condenser and an inlet pipeline of the evaporator in sequence. The refrigerant liquid absorbs heat from a heating element of a server in a computer room through the indoor evaporator and turns into a refrigerant gas. The refrigerant gas rises up through an outlet pipeline of the evaporator and an inlet pipeline of condenser and enters the outdoor condenser, where the refrigerant gas is cooled down by an outdoor natural cold source (such as air or water) and turns into a liquid. Next, the refrigerant liquid flows back through the liquid pipelines for evaporation, thereby forming a cooling cycle.

In implementation, because an outdoor temperature is lower in winter, there is likely a phenomenon of lower condensation pressure during operation in extreme weather, resulting in poor liquid supply capacity, which in turn leads to shortage of liquid in the indoor evaporator and significant decrease in refrigerating capacity of the system. In this case, the refrigerant may be heated by means of the heating sleeve to increase the condensation pressure.

It is worth mentioning that the various pipelines in the present disclosure may be connected through flanges, or other connectors and connection modes may be used, but the present disclosure is not limited thereto.

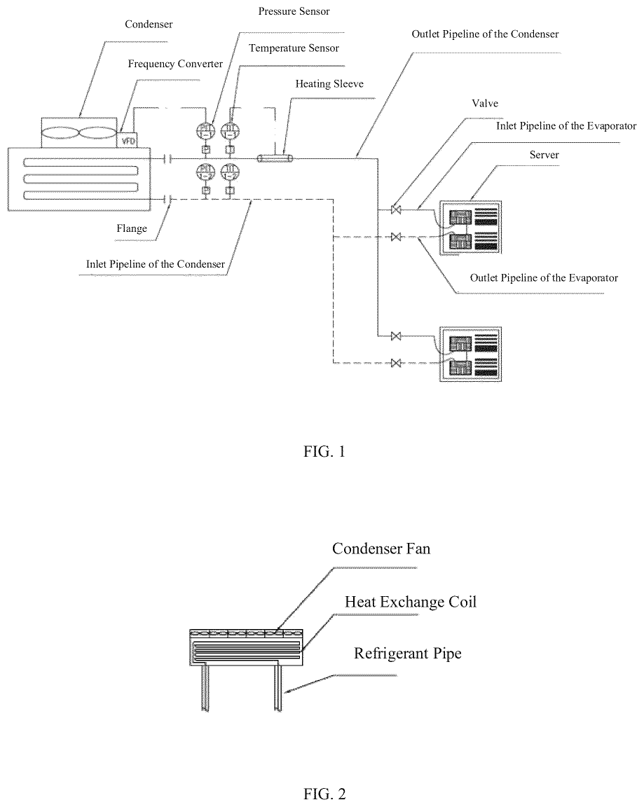

In one embodiment, referring to FIG. 2, the condenser may include a condenser fan, a heat exchange coil, and a refrigerant pipe.

In implementation, the condenser fan is configured to provide power to outdoor air, such that the outdoor air flows through the outdoor condenser and takes away the heat released by the refrigerant in the heat exchange coil.

A water inlet end and a water outlet end of the heat exchange coil are connected to pipelines inside the liquid-cooled container by means of the refrigerant pipe, respectively. A water inlet end and a water outlet end of a cold plate of the server are connected to the hose by means of a quick coupler, respectively. The quick coupler can ensure that the server has online plug maintenance performance.

In one embodiment, a pressure sensor and a frequency converter are also arranged on the outlet pipeline of the outdoor condenser.

In implementation, an outlet pressure of the condenser can be controlled by means of the pressure sensor arranged on the outlet pipeline of the outdoor condenser. Specifically, a current outlet pressure of the outlet pipeline of the condenser is measured in real time by means of the pressure sensor. Next, the current outlet pressure is compared with the preset operating condition. When the current outlet pressure is lower, a liquid supply pressure of the condenser may be increased by means of the frequency converter. When the current outlet pressure is higher, the liquid supply pressure of the condenser may be decreased by means of the frequency converter.

It is to be understood that because the outdoor temperature is higher in summer, the pressure of the refrigerant in the outlet pipeline of the outdoor condenser generally is higher. In this case, the condensation pressure may be appropriately reduced.

Methods for adjusting the liquid supply pressure may include: adjusting revolution speed of the condenser fan of the condenser, adjusting number of the condenser fans of the condenser in operation, and adjusting a liquid supply flow of the outlet pipeline of the condenser, etc., but the present disclosure is not limited thereto.

In one embodiment, a pressure sensor and a temperature sensor are arranged on an inlet pipeline of the outdoor condenser.

In implementation, the pressure sensor and the temperature sensor may also be arranged on the inlet pipeline of the outdoor condenser, making it easier to calculate a pressure differential between the liquid supply pressure and a liquid return pressure and a temperature differential for the refrigerant.

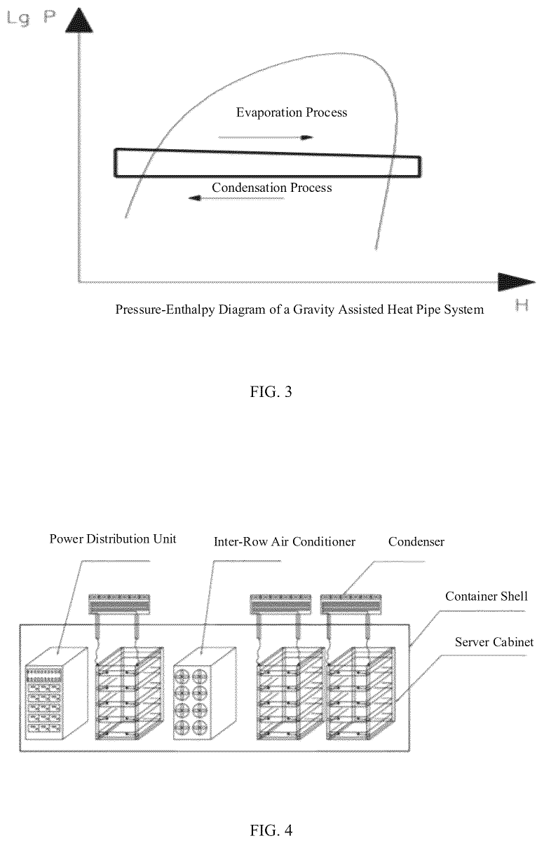

FIG. 3 is a pressure-enthalpy diagram of a gravity assisted heat pipe system according to an embodiment of the present disclosure. The vertical axis lg P represents a logarithmic value of the pressure, and the horizontal axis H represents an enthalpy value. In the present disclosure, the refrigerant relies on gravity to form a natural circulation. Because the outdoor condenser is arranged higher than the indoor evaporator, the condensation temperature may be lower than an evaporation temperature. Rise in the condensation temperature is more conducive to the heat dissipation from a loop heat pipe to the natural cold source, thereby improving utilization rate of the natural cold source of the loop heat pipe.

In one embodiment, a valve is arranged on the outlet pipeline and the inlet pipeline of the indoor evaporator, respectively.

In implementation, the valve may be, for example, an expansion valve, a stop valve, or a solenoid valve, but the present disclosure is not limited thereto.

The liquid cooling system may include a plurality of sets of evaporators to dissipate heat from different servers. The outlet pipeline of each evaporator converges into the inlet pipeline of the condenser, and the outlet pipeline of the condenser is divided into a plurality of branches, which are connected to the inlet pipeline of each evaporator. The inlet pipeline and the outlet pipeline of the evaporator may be independently opened/closed and adjusted by means of the valve. In this way, a cooling range or refrigerating capacity of the system can be independently controlled. For example, when a certain server is no longer in use, the liquid cooling system may be controlled to no longer supply the refrigerant to the server by closing the valves on the inlet and outlet pipelines of the evaporator.

In one embodiment, the indoor evaporator includes an evaporative liquid cooling cold plate, which is attached to the heating element of the server in the data center.

In implementation, attachment of the evaporative liquid cooling cold plate to the heating element of the server in the data center can accelerate heat exchange and improve refrigeration efficiency.

In one embodiment, a thermal conductive coating is provided between the heating element and the evaporative liquid cooling cold plate.

In implementation, the heating element may be a CPU (Central Processing Unit) chip or GPU (Graphics Processing Unit) chip of the server. The thermal conductive coating may use a metal-based material such as metal-based graphene composite coating, or may use a non-metallic-based material such as non-metallic-based silicone grease or organic resin. A method for spraying the thermal conductive coating may be cold spraying, supersonic plasma spraying, or thermal spraying, etc., but the present disclosure is not limited thereto.

In one embodiment, the liquid cooling system may also include a flow distribution unit, which may include a coolant distribution unit, a hose, a quick coupler, and a refrigerant pipe. The refrigerant pipe is connected to the outdoor condenser, and the hose is connected to the evaporative liquid cooling cold plate of the indoor evaporator by means of the quick coupler.

In implementation, the coolant distribution unit may be a manifold configured to connect water inlet and outlet pipelines of various liquid cooling cold plates. A connection method of the hose may be vertebral tube buckle type or clamp-on design, or other connection methods may also be used, but the present disclosure is not limited thereto.

The technical effects generated by the above embodiments are as below. In one aspect, the liquid cooling system of the present disclosure is simple and compact in structure, good in heat transfer performance, and high in reliability. Circulation of the refrigerant is completed by means of gravity assisted heat pipe technology, such that the refrigerant in the liquid cooling system does not need to be transported by a conventional water pump, which reduces pumping power consumption. Compared to a conventional two-stage heat exchange system, the present disclosure reduces primary heat exchange, which further improves the energy utilization ratio of a cooling system of the data center, and reduces structural complexity of the system. In another aspect, in the present disclosure, the current outlet temperature of the outdoor condenser is measured by means of the temperature sensor arranged on the outlet pipeline of the condenser, and the operating state of the heating sleeve on the pipeline is controlled according to the temperature data. When extreme operating conditions are encountered in winter and the outdoor temperature is lower, the outlet refrigerant has a larger degree of supercooling, resulting in less refrigerant flowing to the evaporator and drop of pressure. In this case, the heating sleeve may be started to electrically heat the refrigerant, thereby increasing the temperature of the refrigerant in the outlet pipeline of the condenser. In this way, a liquid supply temperature and a liquid supply pressure may be controlled to maintain at the preset operating condition, thereby ensuring that the end liquid supply temperature is higher than an indoor dew point temperature.

Based on the same inventive concept, the present disclosure also provides an edge data center. Referring to FIG. 4, the edge data center may include a server cabinet and a liquid cooling system, and the edge data center also includes a container shell. The liquid cooling system includes: an outdoor condenser, an indoor evaporator, a temperature sensor, and a heating sleeve. The outdoor condenser and the indoor evaporator are connected through a pipeline to form a loop, and the outdoor condenser is arranged higher than the indoor evaporator. The temperature sensor and the heating sleeve are arranged on the outlet pipeline of the outdoor condenser.

In one embodiment, the edge data center provided in the present disclosure may also include an indoor inter-row air conditioner and a power distribution monitoring unit, where the power distribution monitoring unit is configured to monitor and control an operating state of the inter-row air conditioner.

In implementation, the air-cooled air conditioner may be employed to dissipate heat from non-liquid cooled components in a data center computer room.

In one embodiment, the inter-row air conditioner is a fluorine pump air-cooled inter-row air conditioner.

In implementation, the fluorine pump air-cooled inter-row air conditioner may be arranged between server cabinets to bear air conditioning load of air-cooling portion and cool air in the data center computer room. The air-cooling portion of the server may account for 10-15% of total heat release.

Referring to FIG. 4, the data center computer room includes a container shell and adopts a containerized layout. One or more power distribution monitoring units, one or more server cabinets, and one or more air-cooled air conditioners may be arranged inside the liquid-cooled container. The liquid cooling system may be installed on the server cabinets, and each of the server cabinets is provided with a corresponding liquid cooling system. One liquid cooling system is used for cooling one corresponding server cabinet, and of course, one liquid cooling system may also be used for cooling a plurality of corresponding server cabinets.

In FIG. 4, the outdoor condenser is arranged at a top outside the container. In this way, based on technical principles of the gravity assisted heat pipe technology, the refrigerant in the pipelines can overcome pipeline resistance by taking advantage of gravity reflux and evaporative supercharging, thereby completing circulation of the refrigerant. An evaporation process of the refrigerant is completed in the cold plate of the server, which can take away the heat from the server, and then the absorbed heat is directly dissipated outside by means of the outdoor condenser, thereby reducing intermediate heat exchange processes and pumping power consumption. In the present disclosure, an upper limit of heat exchange can be increased for the liquid cooling cold plate by means of a phase change technology, such that the liquid cooling cold plate is compatible to the liquid cooling system having requirements for higher power density.

It is worth mentioning that the refrigerant may use R134a (that is, 1,1,1,2-tetrafluoroethane, whose chemical formula is C₂H₂F₄) as an environmentally friendly refrigerant, or other refrigerants may also be used, but the present disclosure is not limited thereto.

The edge data center of present disclosure adopts a containerized layout, which can meet requirements for edge high-density computing scenarios. By combining the gravity assisted heat pipe technology with cold plate liquid cooling, circulation of a refrigerant is completed by means of the gravity assisted heat pipe technology, eliminating the need for transporting the refrigerant in the liquid cooling system by means of a conventional water pump, thereby reducing the pumping power consumption. Compared to a conventional two-stage heat exchange system, the present disclosure reduces primary heat exchange, which further improves the energy utilization ratio of a cooling system of the data center, and reduces structural complexity of the system. In addition, the thermal conductive coating is arranged between the heating element of the server and the cold plate, which can enhance heat exchange.

Based on the same inventive concept, the present disclosure also provides a control method for a liquid cooling system, where the control method is applied to the liquid cooling system described in any one of the above embodiments. The control method includes: detecting a current outlet temperature of the outdoor condenser by means of a temperature sensor;
comparing the current outlet temperature with a preset operating condition; and
determining whether to heat a refrigerant by means of a heating sleeve according to a temperature comparison result.

Further, The control method also includes:
detecting a current outlet pressure of the outdoor condenser by means of a pressure sensor;
comparing the current outlet pressure with the preset operating condition; and
determining whether to regulate a liquid supply pressure of the condenser by means of a frequency converter according to a pressure comparison result.

Further, the preset operating condition includes a preset temperature and a preset pressure.

In one embodiment, due to higher outlet temperature of the liquid cooling system, an annual Cooling Load Factor (CLF) of the liquid cooling system generally may be reduced by more than 60% in various scenarios.

In one embodiment, due to use of the gravity assisted heat pipe technology instead of transporting the refrigerant by means of a conventional water pump, an annual Power Usage Efficiency (PUE) of the liquid cooling system is reduced from 1.13 (air conditioning factor is 0.08, and power factor is 0.05) to 1.07 (the air conditioning factor is 0.02, and the power factor is 0.05). The use of the evaporative liquid cooling cold plate significantly increases a heat dissipation upper limit of power consumption of a single chip, such that heat dissipation capability of the single chip approaches the upper limit (700-900 W) under single-phase coolant technology conditions. Thus, the evaporative liquid cooling cold plate can greatly improve the heat dissipation capability of the single chip and assist in iteration of chip heat dissipation technologies.

The foregoing descriptions are merely preferred embodiments of the present disclosure, and are not intended to limit the present disclosure. Any modification, equivalent replacement and improvement made within the spirit and principle of the present disclosure shall fall into the protection scope of the present disclosure.

What is claimed is:

1. A liquid cooling system for a data center, comprising: an outdoor condenser, an indoor evaporator, a temperature sensor, and a heating sleeve; wherein
the outdoor condenser and the indoor evaporator are connected through a pipeline to form a loop, and the outdoor condenser is arranged higher than the indoor evaporator; and
the temperature sensor and the heating sleeve are arranged on an outlet pipeline of the outdoor condenser.

2. The liquid cooling system as claimed in claim 1, wherein a pressure sensor and a frequency converter are further arranged on the outlet pipeline of the outdoor condenser.

3. The liquid cooling system as claimed in claim 1, wherein a pressure sensor and a temperature sensor are arranged on an inlet pipeline of the outdoor condenser.

4. The liquid cooling system as claimed in claim 1, wherein a valve is arranged on the outlet pipeline and the inlet pipeline of the indoor evaporator, respectively.

5. The liquid cooling system as claimed in claim 1, wherein the indoor evaporator comprises an evaporative liquid cooling cold plate attached to a heating element of a server in the data center.

6. The liquid cooling system as claimed in claim 5, wherein a thermal conductive coating is provided between the heating element and the evaporative liquid cooling cold plate.

7. An edge data center comprising a server cabinet and a liquid cooling system, wherein the edge data center further comprises a container shell; the liquid cooling system comprises: an outdoor condenser, an indoor evaporator, a temperature sensor, and a heating sleeve;
the outdoor condenser and the indoor evaporator are connected through a pipeline to form a loop, and the outdoor condenser is arranged higher than the indoor evaporator; and
the temperature sensor and the heating sleeve are arranged on an outlet pipeline of the outdoor condenser.

8. The edge data center as claimed in claim 7 further comprising an indoor inter-row air conditioner and a power distribution monitoring unit, wherein the power distribution monitoring unit is configured to monitor and control an operating state of the inter-row air conditioner.

9. The edge data center as claimed in claim 8, wherein the inter-row air conditioner is a fluorine pump air-cooled inter-row air conditioner.

10. A control method for a liquid cooling system, wherein the control method is applied to a liquid cooling system comprising an outdoor condenser, an indoor evaporator, a temperature sensor, and a heating sleeve, the control method comprising:
detecting a current outlet temperature of the outdoor condenser by means of a temperature sensor;
comparing the current outlet temperature with a preset operating condition; and
determining whether to heat a refrigerant by means of a heating sleeve according to a temperature comparison result.

11. The control method for the liquid cooling system as claimed in claim 10, further comprising:
detecting a current outlet pressure of the outdoor condenser by means of a pressure sensor;
comparing the current outlet pressure with the preset operating condition; and
determining whether to regulate a liquid supply pressure of the condenser by means of a frequency converter according to a pressure comparison result.

12. The control method for the liquid cooling system as claimed in claim 10, wherein the preset operating condition comprises a preset temperature and a preset pressure.
